(19) United States
(12) Patent Application Publication
(10) Pub. No.: US 2025/0267869 A1
(43) Pub. Date: Aug. 21, 2025

(54) MEMORY DEVICE AND METHOD OF FABRICATING THE SAME

(71) Applicant: MACRONIX International Co., Ltd., Hsinchu (TW)

(72) Inventors: Chen-Yu Cheng, Hsinchu City (TW); Tzung-Ting Han, Hsinchu City (TW)

(73) Assignee: MACRONIX International Co., Ltd., Hsinchu (TW)

(21) Appl. No.: 18/582,677

(22) Filed: Feb. 21, 2024

(51) Int. Cl. H10B 43/35; H10B 43/27

(52) U.S. Cl. CPC H10B 43/35; H10B 43/27

(57) ABSTRACT

A memory device includes a stacked structure, a second conductive layer, channel pillars, and a string selection line cut slit. The stacked structure includes first insulating layers and first conductive layers stacked alternately. The second conductive layer is above the stacked structure. The channel pillars extend through the second conductive layer and the stacked structure. Each channel pillar includes a first portion and a second portion. The first portion extends through the stacked structure. The second portion is located on the first portion and extends through the second conductive layer. A diameter of the first portion is greater than a diameter of the second portion. The string selection line cut slit extends through the second conductive layer and is disposed between the second portions of two adjacent channel pillars. The memory device can be applied to 3D NAND flash memory to create memory devices with high capacity and performance.

### BACKGROUND

### Technical Field

The embodiments of the disclosure relate to a semiconductor device and a method of fabricating the same, and particularly, to a memory device and a method of fabricating the same.

### Related Art

A non-volatile memory has the advantage that stored data does not disappear at power-off, so it becomes widely used for a personal computer or other electronic equipment. Currently, the three-dimensional (3D) memory commonly used in the industry includes a NOR memory and a NAND memory. In addition, another type of 3D memory is an AND memory, which can be applied to a multi-dimensional memory array with high integration and high area utilization, and has an advantage of a high operation speed. Therefore, the development of a 3D memory device has gradually become the current trend.

### SUMMARY

The embodiments of the disclosure provide a memory device and a method of fabricating the same capable of reducing the distance between devices to reduce the chip area occupied.

An embodiment of the disclosure provides a memory device including a stacked structure, a second conductive layer, a plurality of channel pillars, a plurality of charge storage structures, and a string selection line cut slit. The stacked structure includes a plurality of first insulating layers and a plurality of first conductive layers stacked alternately with each other. The second conductive layer is located over the stacked structure. The plurality of channel pillars extend through the second conductive layer and the stacked structure. Each of the plurality of channel pillars includes a first portion and a second portion. The first portion extends through the stacked structure. The second portion is located on the first portion and extends through the second conductive layer. A diameter of the first portion is greater than a diameter of the second portion. The plurality of charge storage structures surround the plurality of channel pillars and are in contact with the second conductive layer. The string selection line cut slit extends through the second conductive layer and is disposed between the second portions of two adjacent channel pillars among the plurality of channel pillars.

An embodiment of the disclosure provides a memory device including a stacked structure, a second conductive layer, a string selection line cut slit, a plurality of first channel pillars, and a plurality of second channel pillars. The stacked structure includes a plurality of insulating layers and a plurality of first conductive layers stacked alternately with each other. The second conductive layer is located between the stacked structure and an interconnect layer having a plurality of conductive plugs. The string selection line cut slit has a wavy shape in a top view. The string selection line cut slit extends through the second conductive layer and divides the second conductive layer into a first sub-zone and a second sub-zone. The plurality of first channel pillars extend through the second conductive layer and the stacked structure in a first sub-zone. The plurality of second channel pillars extend through the second conductive layer and the stacked structure in a second sub-zone.

An embodiment of the disclosure provides a method of fabricating a memory device, including steps below. A stacked structure is formed, the stacked structure including a plurality of first insulating layers and a plurality of intermediate layers stacked alternately with each other over a substrate. A plurality of first openings are formed in the stacked structure. The plurality of first openings are filled with a sacrificial material. A conductive layer is formed over the stacked structure. The conductive layer is patterned to form a plurality of second openings and a trench between the plurality of second openings. A width of the trench is smaller than diameters of the plurality of second openings. The sacrificial material is removed to expose the plurality of first openings below the plurality of second openings. A plurality of channel pillars are formed in the plurality of first openings and the plurality of second openings. A string selection line cut slit is formed in the trench.

Based on the above, the memory device and the method of fabricating the same according to the embodiments of the disclosure can reduce the distance between devices to reduce the chip area occupied.

### BRIEF DESCRIPTION OF DRAWINGS

FIG. 1A to FIG. 1J are schematic cross-sectional views of a fabrication process of a memory device according to an embodiment of the disclosure.

FIG. 2A and FIG. 2B are schematic enlarged views of partial regions in FIG. 1F and

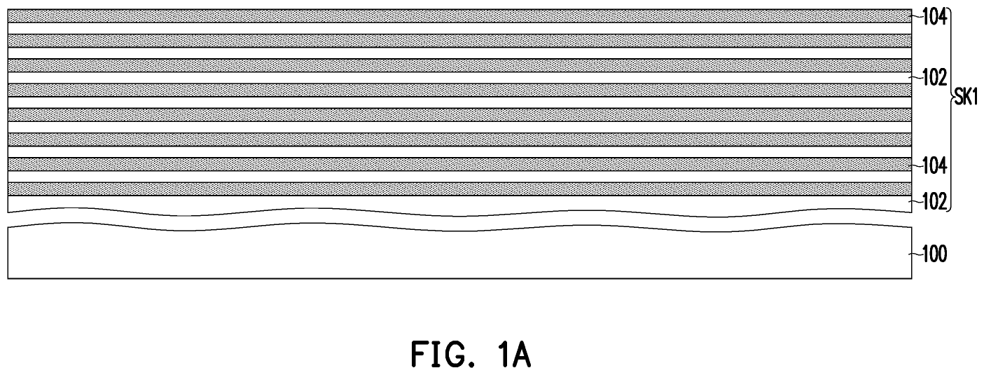

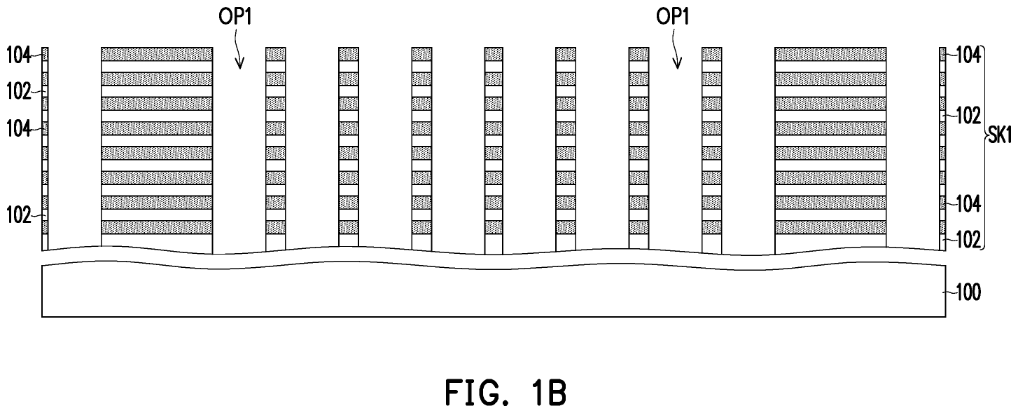

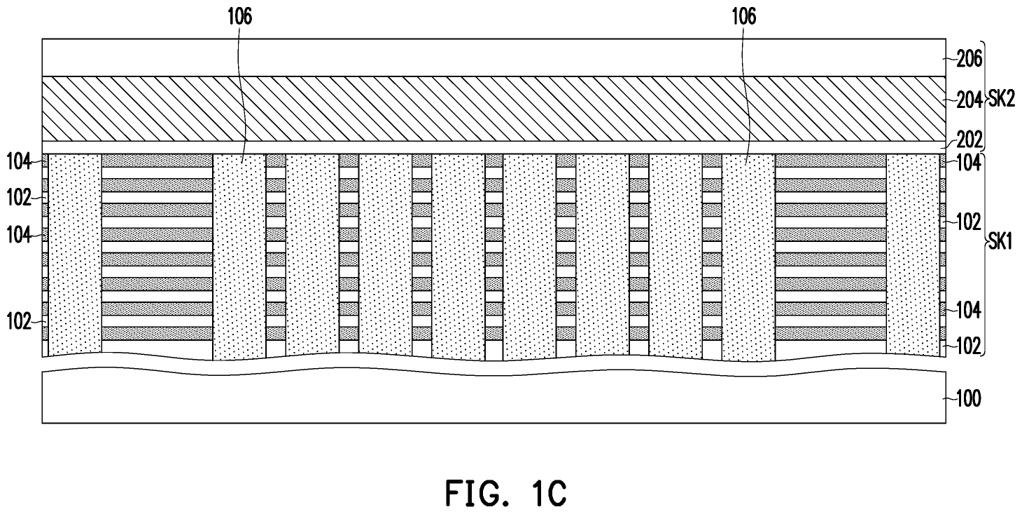

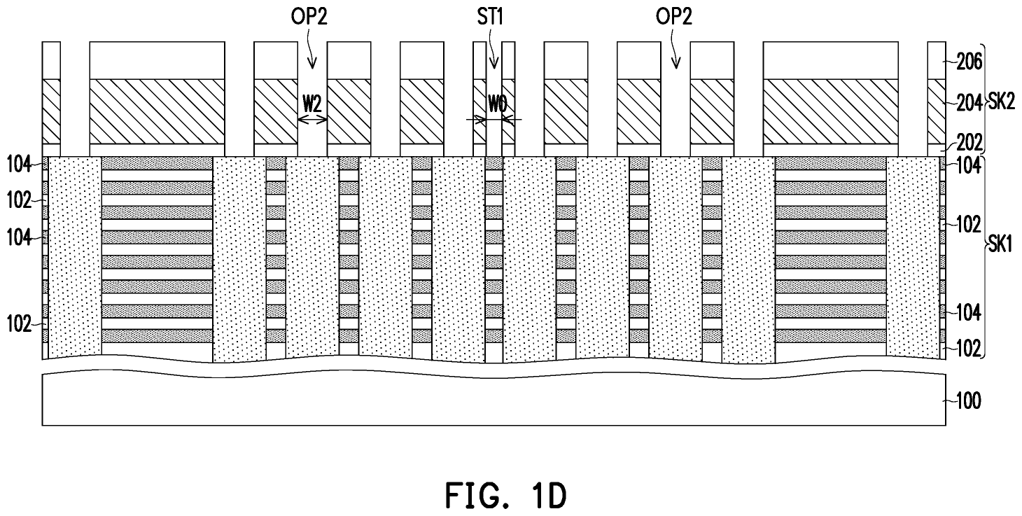

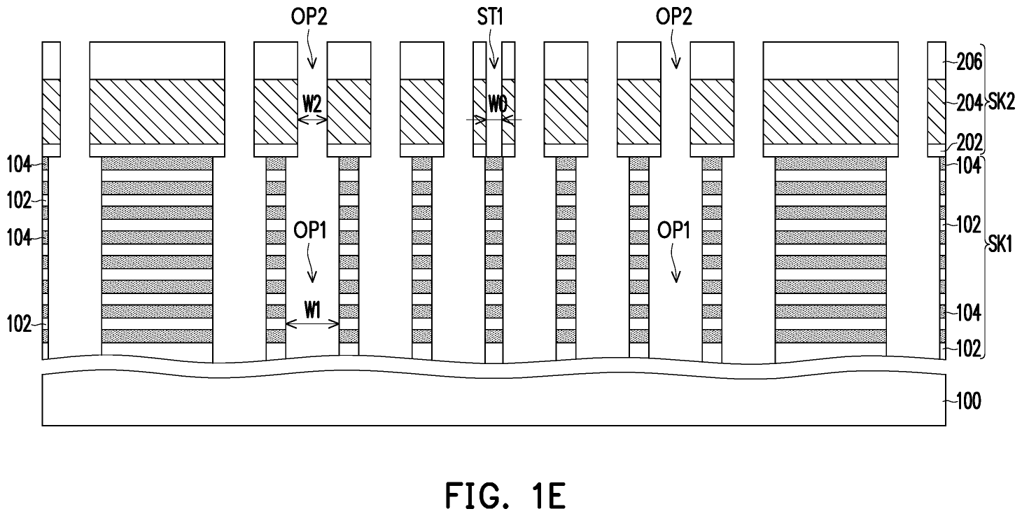

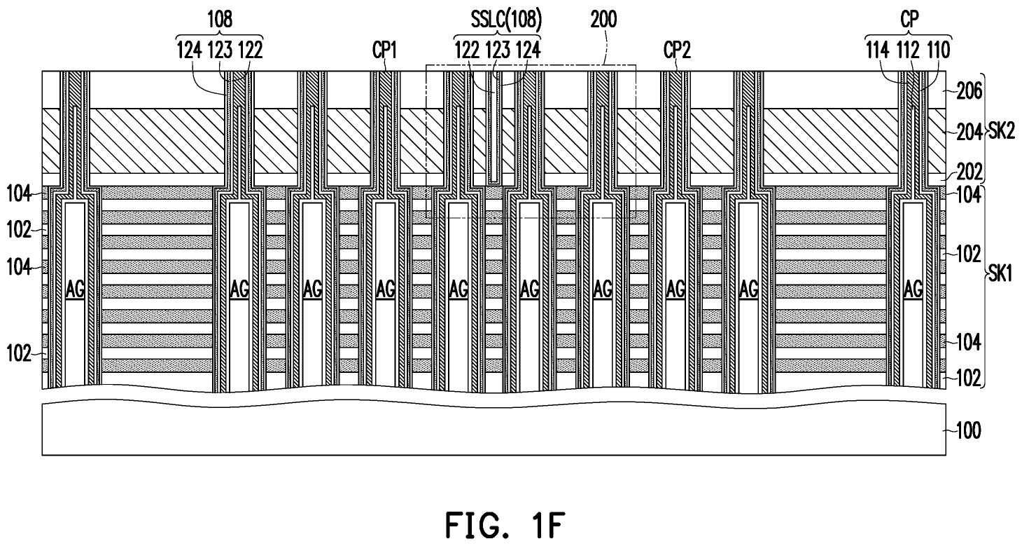

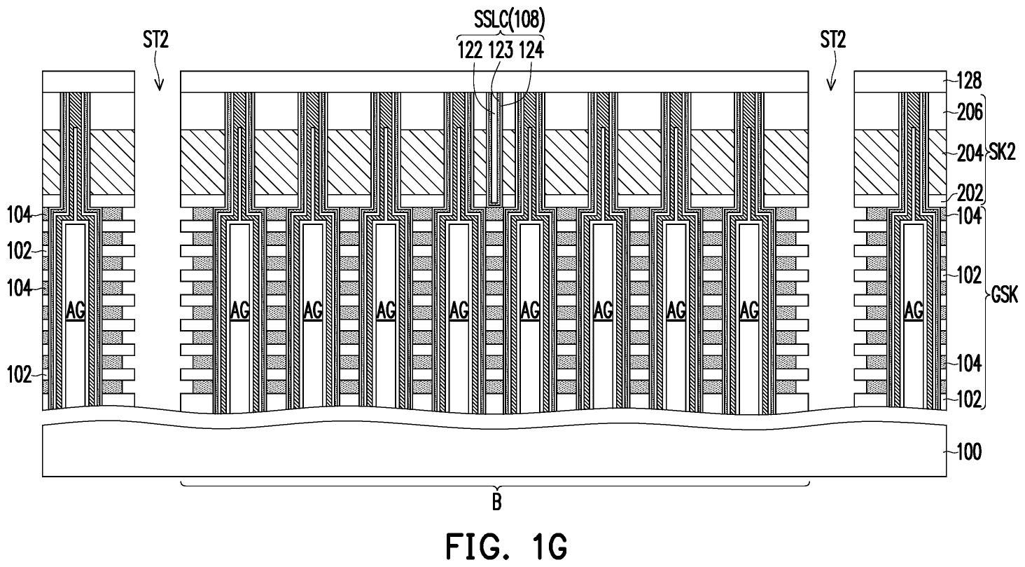

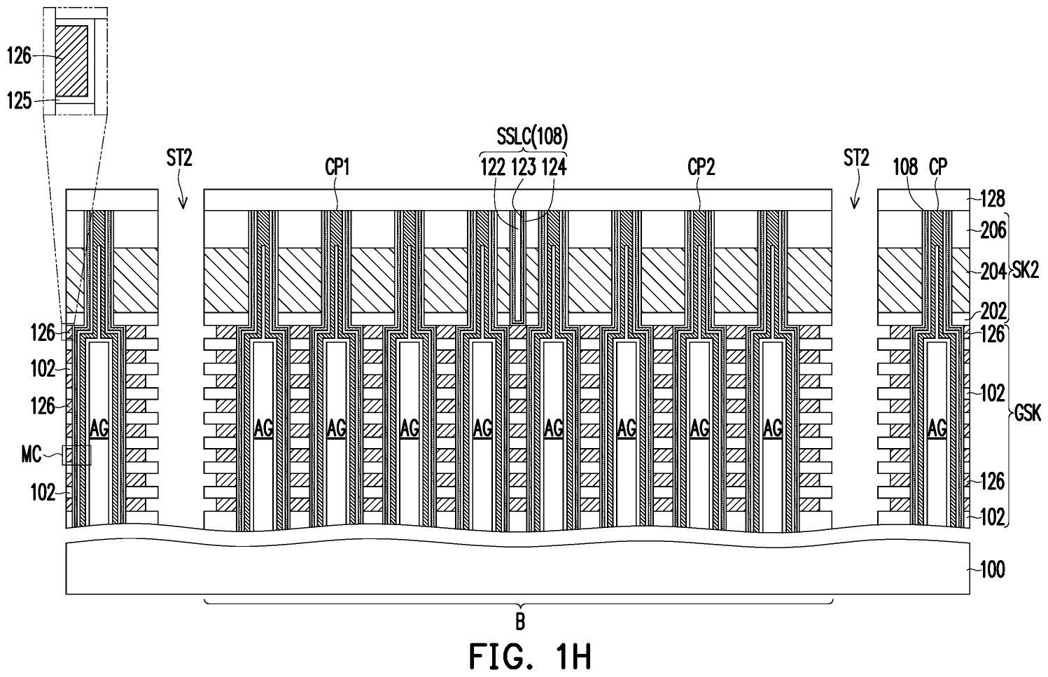

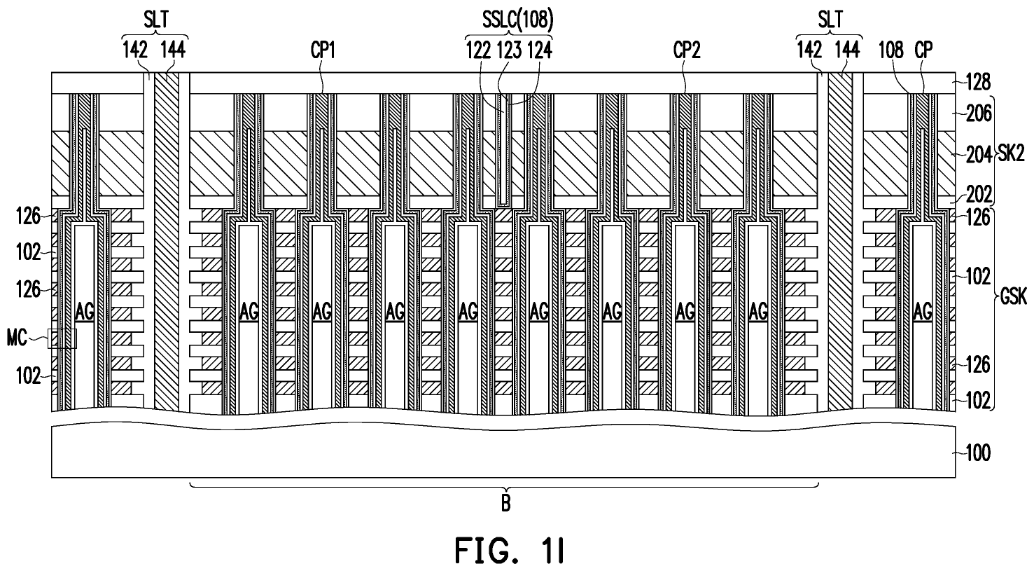

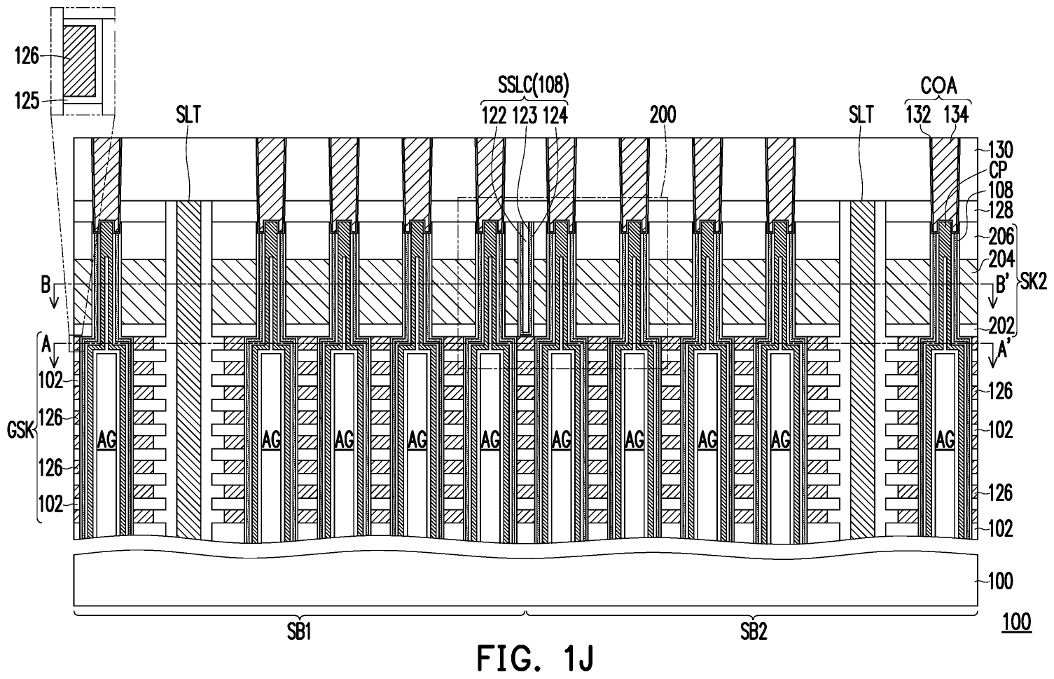

FIG. 1J, respectively.

FIG. 3A is a top view along line A-A′ in FIG. 1J.

FIG. 3B is a top view along line B-B′ in FIG. 1J.

FIG. 4 is a schematic cross-sectional view of a memory device having a complementary metal-oxide-semiconductor under array (CMOS under array, CuA) structure according to an embodiment of the disclosure.

FIG. 5 is a schematic cross-sectional view of a memory device having a complementary metal-oxide-semiconductor bonding array (CMOS bonding array, CbA) structure according to an embodiment of the disclosure.

### DESCRIPTION OF EMBODIMENTS

As sizes of devices continue to decrease, the distance between the devices is also required to gradually decrease to reduce the chip area occupied. The embodiments of the disclosure change structures of a drain-side select gate, a channel pillar, and a string selection line cut slit to reduce the distance between the string selection line cut slit and the channel pillar and save the chip area.

FIG. 1A to FIG. 1J are schematic cross-sectional views of a fabrication process of a memory device according to an embodiment of the disclosure.

Referring to FIG. 1A, a substrate 100 is provided. The substrate 100 includes an array region (not shown) and a staircase region (not shown). The substrate 100 may be a semiconductor (e.g., silicon) substrate. A stacked structure SK1 is formed over the substrate 100. The stacked structure SK1 may also be referred to as an insulating stacked structure SK1. In this embodiment, the stacked structure SK1 comprises insulating layers 102 and intermediate layers 104 sequentially stacked alternately with each other above the substrate 100. The insulating layer 102 is, for example, a silicon oxide layer. The intermediate layer 104 is, for example, a silicon nitride layer. The intermediate layer 104 may serve as a sacrificial layer to be partially removed in subsequent processes. In one example as shown in FIG. 4, a device layer 60, an interconnect structure 70, and a source line layer SL may be formed between the substrate 100 and the stacked structure SK1. The device layer 60 may include complementary metal-oxide-semiconductor devices. In another example, the stacked structure SK1 is formed on the substrate 100.

Next, the stacked structure SK1 is patterned to form a staircase structure (not shown) in the staircase region. Afterwards, a dielectric layer (not shown) is formed on the staircase structure. The material of the dielectric layer (not shown) is, for example, silicon oxide. The dielectric layer (not shown) may be planarized by a planarization process such as a chemical-mechanical polishing process.

Next, referring to FIG. 1B, a plurality of openings OP1 are formed in the array region of the stacked structure SK1. The openings OP1 may penetrate the stacked structure SK1 and further extend to underlying layers (not shown). In this embodiment, in a top view, the opening OP1 has a circular profile (not shown), but the disclosure is not limited thereto. In some embodiments, the upper width of the opening OP1 is greater than the lower width thereof, and the cross-section of the opening OP1 has, for example, a conical shape.

Referring to FIG. 1C, a sacrificial material is formed on the stacked structure SK1 and in the openings OP1. Afterwards, an etch-back process or a chemical-mechanical polishing process is performed to remove the excess sacrificial material on the stacked structure SK1 to form a plurality of sacrificial pillars 106 respectively in the plurality of openings OP1. The material of the sacrificial pillar 106 is different from the insulating layer 102 and is also different from the intermediate layer 104. The sacrificial pillar 106 is, for example, amorphous silicon, tungsten, or a carbon-containing organic material. The carbon-containing organic material may be a polymer such as a photoresist. The photoresist may be a positive photoresist or a negative photoresist. The material of the sacrificial pillar 106 is not limited thereto, and other materials may also be used. The sacrificial pillar 106 has a circular profile (not shown).

Referring to FIG. 1C, a stacked structure SK2 is formed on the stacked structure SK1. In this embodiment, the stacked structure SK2 may comprise an insulating layer 202, a conductive layer 204 (also referred to as drain-side select gate or SGD), and an insulating layer 206. The materials of the insulating layers 202 and 206 may respectively be the same as or similar to the insulating layer 102. The material of the conductive layer 204 may be semiconductor, metal, metal silicide, or a combination thereof. The semiconductor may be, for example, polysilicon. The metal may be, for example, tungsten. The metal silicide may be, for example, titanium silicide. The conductive layer 204 may be one layer or multiple layers.

Referring to FIG. 1D, next, photolithography and etching processes are performed to pattern the stacked structure SK2 to form a plurality of openings OP2 and a slit trench ST1. The openings OP2 respectively expose the sacrificial pillars 106. The slit trench ST1 exposes the topmost intermediate layer 104. A width W0 of the slit trench ST1 is smaller than a width W2 of the opening OP2. A slit trench ST1 has a strip shape (not shown).

Referring to FIG. 1E, the plurality of sacrificial pillars 106 exposed by the plurality of openings OP2 are removed to form a plurality of openings OP1. When the plurality of sacrificial pillars 106 are a carbon-containing organic material, the sacrificial pillars 106 may be removed by a dry removal method such as oxygen plasma ashing without issues of over-etching or an insufficient etching depth (open) of the opening OP1. A width W1 of the opening OP1 is greater than the width W2 of the opening OP2.

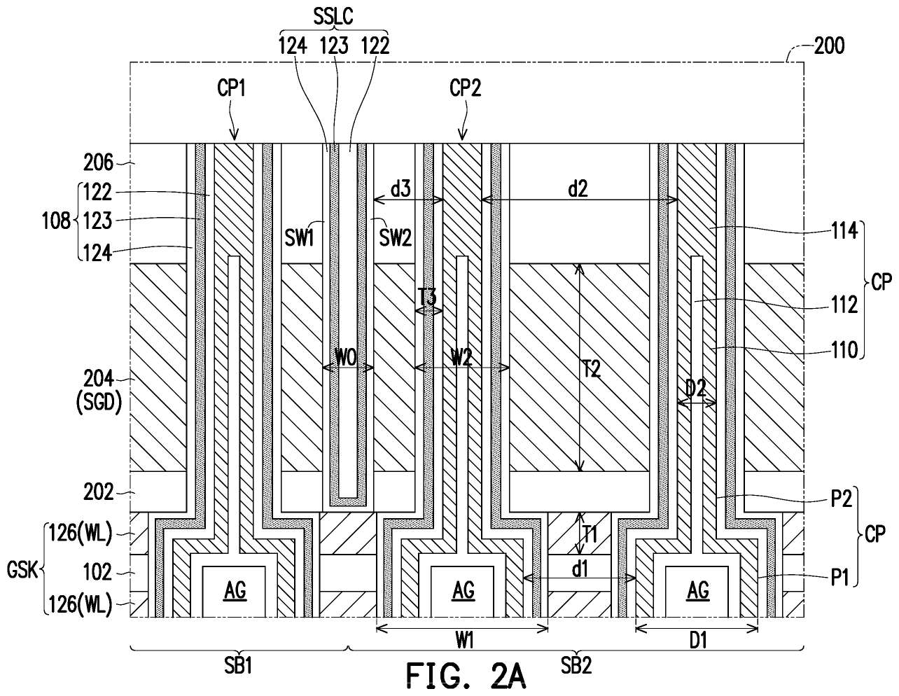

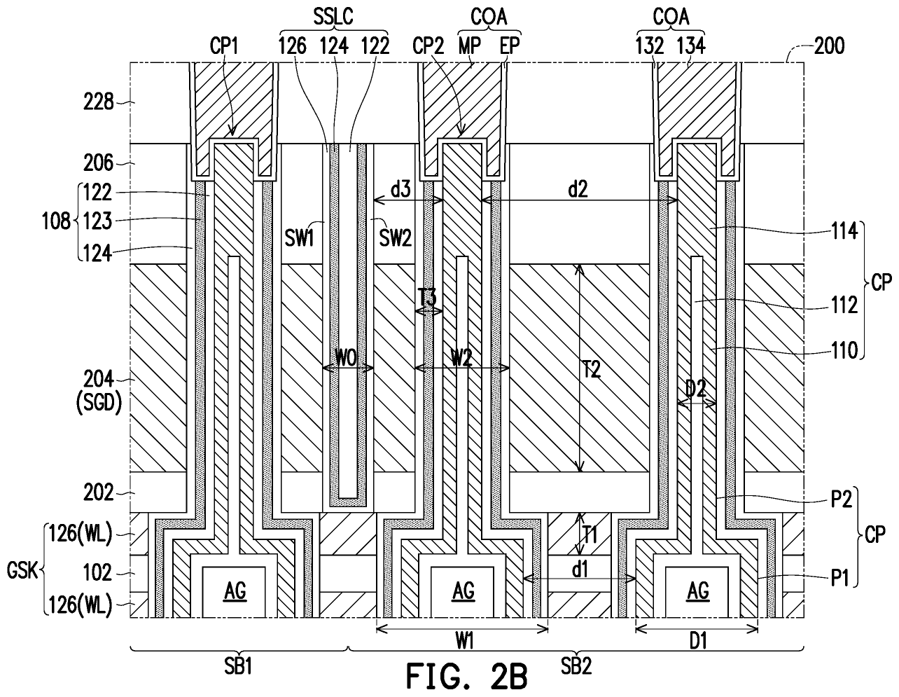

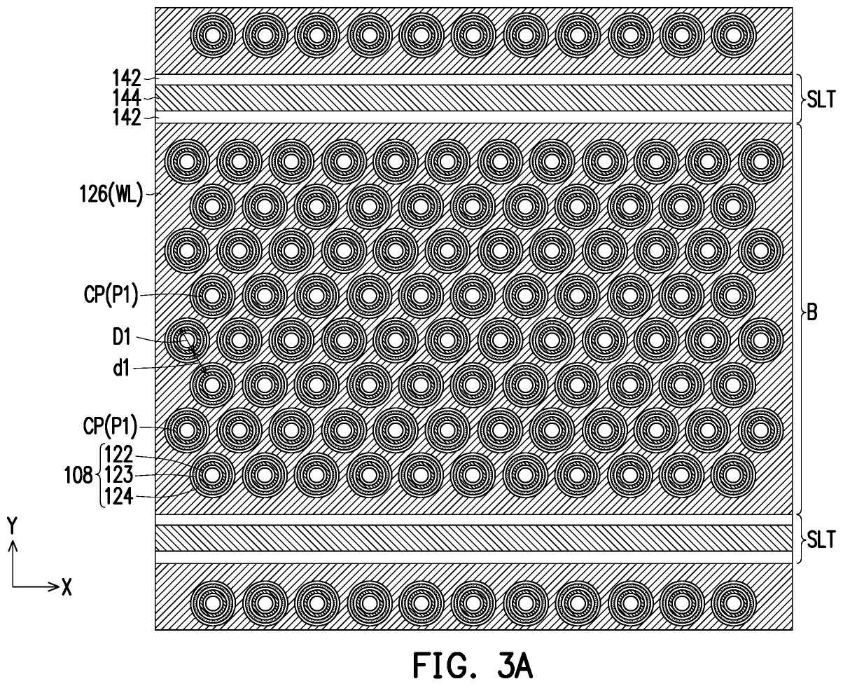

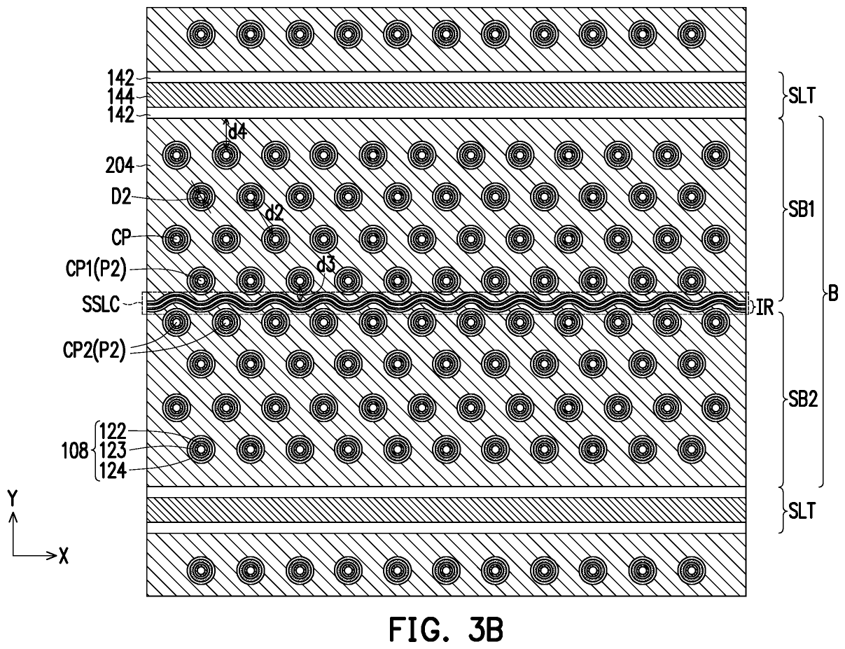

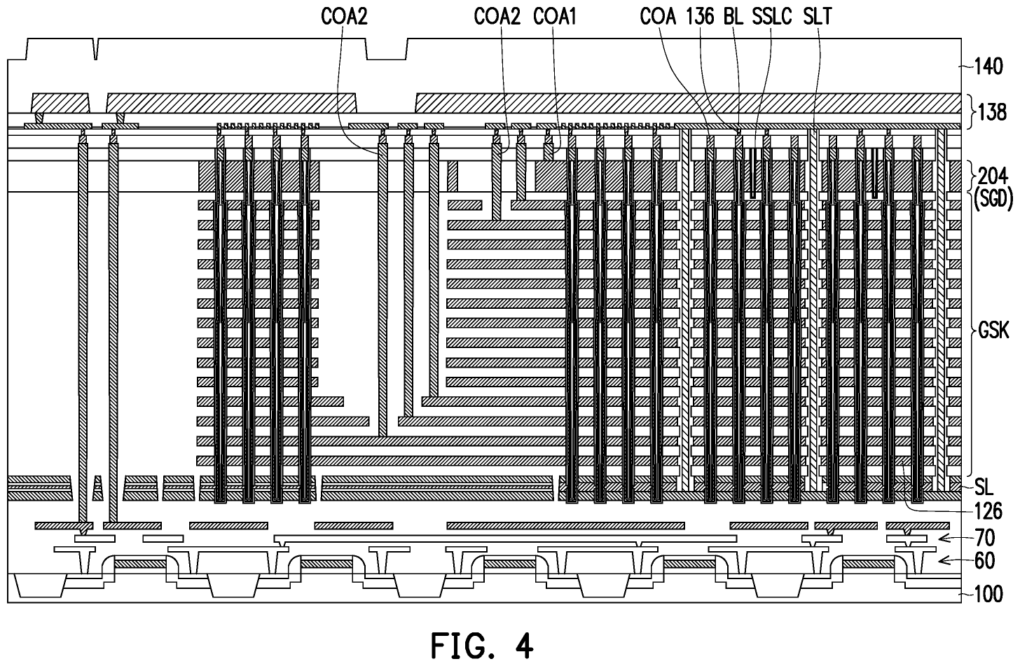

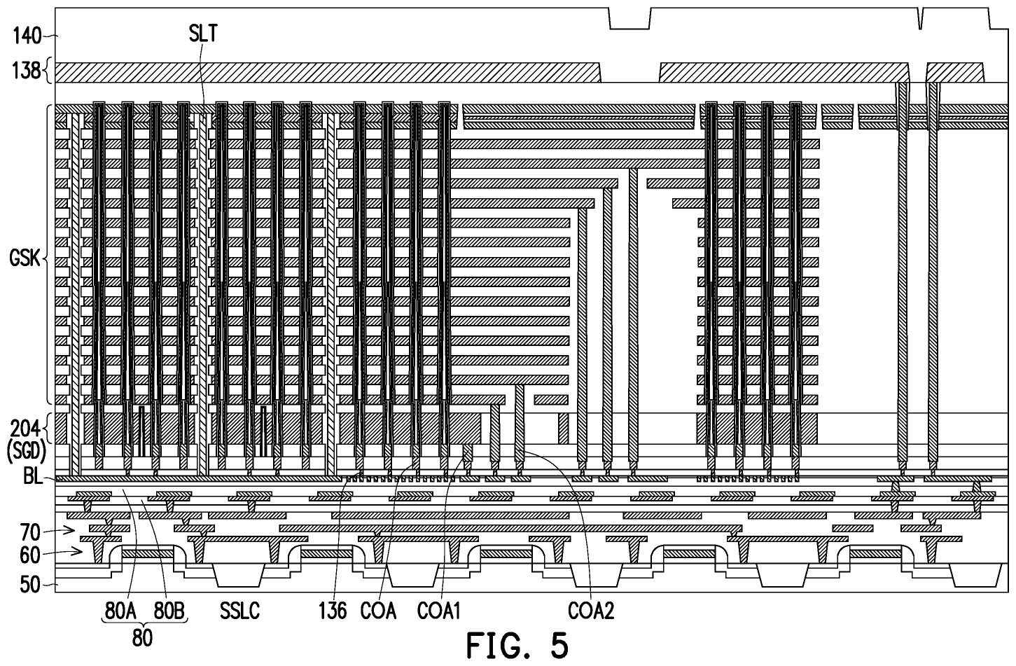

Afterwards, referring to FIG. 1F, a charge storage structure 108 and a channel pillar CP are formed in the openings OP2 and OP1, and a string selection line cut slit SSLC is formed in the slit trench ST1. For clarity, FIG. 2A shows a schematic enlarged view of a region 200 in FIG. 1F. The formation methods of the charge storage structure 108 and the channel pillar CP will be described in detail with reference to FIG. 2A.

Referring to FIG. 1F and FIG. 2A, the charge storage structure 108 is formed in the openings OP2 and OP1 (shown in FIG. 1F). The charge storage structure 108 may include a blocking layer 124, a charge storage layer 123, and a tunneling layer 122. The tunneling layer 122 is, for example, silicon oxide. The charge storage layer 123 is, for example, silicon nitride. The blocking layer 124 is, for example, silicon oxide or a material with a high dielectric constant greater than or equal to 7, such as aluminum oxide (Al₂O₃), hafnium oxide (HfO₂), lanthanum oxide (La₂O₅), transition metal oxide, lanthanide element oxide, or a combination thereof. In the embodiments of the disclosure, the charge storage structure 108 is also filled into the slit trench ST1. The width W0 of the slit trench ST1 is smaller than twice a thickness T3 of the charge storage structure 108. Therefore, at this stage, the slit trench ST1 is filled up by the charge storage structure 108 to form the string selection line cut slit SSLC. The width W2 of the opening OP2 and the width W1 of the opening OP1 are greater than the width W0 of the slit trench ST1, and are greater than twice the thickness T3 of the charge storage structure 108. That is, W0<2T3<W2<W1. Therefore, the charge storage structure 108 cannot fill up the opening OP2 and the opening OP1.

Referring to FIG. 1F and FIG. 2A, the channel pillar CP is formed in the remaining space in the openings OP2 and OP1 (shown in FIG. 1F). First, a channel layer 110 is formed on the charge storage structure 108. In an embodiment, the material of the channel layer 110 includes polysilicon. In an embodiment, the channel layer 110 covers the charge storage structure 108 on the sidewalls of the openings OP2 and OP1, and the channel layer 110 also covers the bottom surface of the opening OP1 (not shown). Then, an insulating layer 112 is formed in the openings OP2 and OP1. In an embodiment, the material of the insulating layer 112 includes silicon oxide. In this embodiment, since the width W2 of the opening OP2 is smaller than the width W1 of the opening OP1, the insulating layer 112 fills up the remaining space in the opening OP2 and seals the opening OP2. Since the width W1 of the opening OP1 is larger, the remaining space therein cannot be filled up by the insulating layer 112, and the insulating layer 112 is on an interior surface of the channel layer 110. An air gap AG encapsulated by the insulating layer 112 is formed in the opening OP1.

Afterwards, the insulating layer 112 and the channel layer 110 in the opening OP2 are etched back to form a groove (not shown), and then a conductive cap 114 is formed in the groove. In an embodiment, the material of the conductive cap 114 includes polysilicon. Subsequently, a chemical-mechanical planarization process is performed to remove the excess charge storage structure 108, insulating layer 112, and channel layer 110 on the insulating layer 206. The channel layer 110, the insulating layer 112, and the conductive cap 114 may be collectively referred to as a channel pillar CP. The charge storage structure 108 surrounds the vertical outer surface of the channel pillar CP.

Referring to FIG. 1G, a cap insulating layer 128 is formed on the insulating layer 206. The cap insulating layer 128 includes silicon oxide, silicon nitride, or a combination thereof. The cap insulating layer 128 may be one layer or multiple layers. Subsequently, a patterning process is performed to form a plurality of slit trenches ST2. The slit trenches ST2 extend through the stacked structures SK2 and SK1.

Referring to FIG. 1H, an etching process such as a wet etching process is performed to remove the plurality of intermediate layers 104 surrounding the slit trenches ST2 to form a plurality of horizontal openings (not shown). Subsequently, a barrier layer 125 and a gate layer (also referred to as a conductive layer) 126 are formed in the horizontal openings. The material of the barrier layer 125 may be, for example, titanium (Ti), titanium nitride (TiN), tantalum (Ta), tantalum nitride (TaN), or a combination thereof. The gate layer 126 may also be referred to as a word line WL. The gate layer 126 is, for example, tungsten, cobalt, or ruthenium. The method for forming the barrier layer 125 and the gate layer 126 includes, for example, sequentially forming a barrier material and a conductive material in the slit trenches ST2 and the horizontal openings, and then performing an etch-back process to form the barrier layer 125 and the gate layer 126 in the plurality of horizontal openings. At this time, a stacked structure GSK has been formed. The stacked structure GSK includes a memory array composed of a plurality of memory cells MC formed by the gate layers 126, the channel pillars CP, and the charge storage structures 108.

Referring to FIG. 1I, separation walls SLT are formed in the slit trenches ST2. The method for forming the separation walls SLT includes filling an insulating liner material and a conductive material on the cap insulating layer 128 and in the slit trenches ST2. The insulating liner material is, for example, silicon oxide. The conductive material is, for example, polysilicon, titanium/titanium nitride, tungsten, or a combination thereof. Then, the excess insulating liner material and conductive material on the cap insulating layer 128 are removed by an etch-back process or a planarization process to form a liner layer 142 and a conductive layer 144. The liner layer 142 and the conductive layer 144 are collectively referred to as a separation wall SLT. In some embodiments, the conductive layer 144 of the separation wall SLT may further encapsulate an air gap. In other embodiments, the separation wall SLT may also be completely filled with the insulating material without any conductive layer. In still other embodiments, the separation wall SLT may also be the liner layer 142, and the liner layer 142 encapsulates an air gap AG without any conductive layer.

Referring to FIG. 1J, a dielectric layer 130 is formed on the cap insulating layer 128. The dielectric layer 130 is, for example, silicon oxide. Subsequently, a conductive plug COA is formed in the dielectric layer 130. The method for forming the conductive plug COA includes, for example, forming a contact hole (not shown) in the dielectric layer 130. The contact hole exposes the top surface and the upper sidewall of the conductive cap layer 114. Then, a barrier layer 132 and a conductive layer 134 are formed in the contact hole. The material of the barrier layer 132 is, for example, titanium (Ti), titanium nitride (TiN), tantalum (Ta), tantalum nitride (TaN), or a combination thereof. The conductive layer 134 is, for example, tungsten. The method for forming the barrier layer 132 and the conductive layer 134 includes, for example, sequentially forming a barrier material and a conductive material on the dielectric layer 130 and in the contact hole, and then performing an etch-back process or a chemical-mechanical polishing process to form a conductive plug COA in the contact hole. As shown in FIG. 4, before, after, or at the same time as the formation of the conductive plug COA, a conductive plug COA1 connected to the conductive layer 204, a conductive plug COA2 connected to the gate layer 126, etc. may be formed. Then, subsequent processes are performed, such as forming a via 136, a bit line BL, an interconnect structure 138, a protective layer 140, etc.

FIG. 2A and FIG. 2B are schematic enlarged views of partial regions 200 in FIG. 1F and FIG. 1J, respectively. FIG. 3A is a top view along line A-A′ in FIG. 1J. FIG. 3B is a top view along line B-B′ in FIG. 1J.

Referring to FIG. 2A, in the embodiments of the disclosure, each of the channel pillars CP includes a first portion P1 and a second portion P2. The first portion P1 is located below the second portion P2 and extends through the stacked structure GSK. The first portion P1 includes the channel pillar 110, the insulating layer 112, and the air gap AG surrounded by the insulating layer 112. The second portion P2 is located above the first portion P1 and extends through the insulating layer 202, the conductive layer 204 (SGD), and the insulating layer 206. The second portion P2 is located above the first portion P1 and is connected to the first portion P1. The second portion P2 includes the conductive cap 114, the insulating layer 112, and the channel layer 110. The insulating layer 112 is located below the conductive cap 114. The channel layer 110 is located below the conductive cap 114 and is located between the charge storage structure 108 and the insulating layer 112. The second portion P2 is free of an air gap AG.

Referring to FIG. 2A, FIG. 3A and FIG. 3B, a diameter D1 of the first portion P1 is greater than a diameter D2 of the second portion P2. In two adjacent or neighboring channel pillars CP, a distance d2 between the two second portions P2 is greater than a distance d1 between the two first portions P1.

Referring to FIG. 2B, in the embodiments of the disclosure, the charge storage structure 108 surrounds the outer surface of the channel pillar CP. More specifically, the charge storage structure 108 surrounds the conductive cap 114, the channel layer 110, and the insulating layer 112. In this embodiment, the top surfaces of the charge storage layer 123 and the tunneling layer 122 of the charge storage structure 108 are also in contact with the bottom surface of the conductive plug COA. The blocking layer 124 of the charge storage layer 123 further extends upward to cover the lower sidewall of the conductive plug COA. In this embodiment, the charge storage structure 108 is in contact with the sidewalls of the insulating layer 206, the conductive layer 204, the insulating layer 202, the gate layers 126, and the insulating layers 102.

Referring to FIG. 2B, in the embodiment of the disclosure, the conductive layer 204 (SGD) may serve as a drain-side select gate. The conductive layer 204 is above the topmost gate layer 126 of the stacked structure GSK. A thickness T2 of the conductive layer 204 is greater than a thickness T1 of the gate layer 126. In some embodiments, the thickness T2 of the conductive layer 204 is 1.5 to 15 times the thickness T1 of the gate layer 126. A top view of the conductive layer 204 is shown in FIG. 3B.

Referring to FIG. 3B, the separation walls SLT and the string selection line cut slit SSLC extend in the same direction, for example, extending in an X direction. The string selection line cut slit SSLC is located between the separation walls SLT. The shape of the string selection line cut slit SSLC is different from the shape of the separation wall SLT. In this embodiment, in the top view, the separation wall SLT has a strip shape, and the string selection line cut slit SSLC has a wavy shape. The string selection line cut slit SSLC is conformal with partial sidewalls of a plurality of channel pillars CP1 and partial sidewalls of a plurality of channel pillars CP2.

Referring to FIG. 1J and FIG. 3B, the separation walls SLT divide the conductive layer 204 and the stacked structure GSK (shown in FIG. 2B) located below into a plurality of zones B. The string selection line cut slit SSLC passes through the conductive layer 204, and divides the conductive layer 204 into a plurality of sub-zones SB1 and SB2. In other words, the string selection line cut slit SSLC is located between the sub-zones SB1 and SB2, so the region around the string selection line cut slit SSLC may also be referred to as an interface region IR. The channel pillars CP1 extend through the conductive layer 204 and the stacked structure GSK in the sub-zone SB1, and the channel pillars CP2 extend through the conductive layer 204 and the stacked structure GSK in the sub-zone SB2. The string selection line cut slit SSLC is disposed between the channel pillars CP1 and CP2 as shown in FIG. 1I and FIG. 3.

Referring to FIG. 2A and FIG. 3B, in this embodiment, the string selection line cut slit SSLC does not pass through a dummy pillar, either. The region (also referred to as an interface region) IR around the string selection line cut slit SSLC is also free of a dummy pillar. Therefore, the string selection line cut slit SSLC is very close to the adjacent or neighboring channel pillar CP1 or CP2. Since it is not required to provide a dummy pillar in the interface region IR, it is possible to save the area of the chip. The dummy pillar mentioned herein may have a structure similar to the channel pillar CP and the charge storage structure 108, but does not provide data storage function.

Referring to FIG. 2B and FIG. 3B, in this embodiment, a distance d3 between the string selection line cut slit SSLC and the second portion P2 of the adjacent or neighboring channel pillar CP is very small. The distance d3 may be smaller than a distance d4 between the separation wall SLT and the second portion P2 of the adjacent or neighboring channel pillar CP. The distance d3 is also smaller than the distance d2 between the second portions P2 of adjacent or neighboring channel pillars CP.

Referring to FIG. 2A and FIG. 3A, the string selection line cut slit SSLC passes through the insulating layer 206, the conductive layer 204 and the insulating layer 202, lands on the topmost conductive layer 126 of the stacked structure GSK, and does not extend beyond the topmost conductive layer 126. In other words, the string selection line cut slit SSLC passes through the conductive layer 204 (SGD), which is single-layered and thicker, above the stacked structure GSK, and does not pass through any one of the conductive layers 126, which are thinner, of the stacked structure GSK. Sidewalls SW1 and SW2 of the string selection line cut slit SSLC are in contact with the conductive layer 204 (SGD).

The size of the string selection line cut slit SSLC is quite small. As shown in FIG. 2A, the width W0 of the string selection line cut slit SSLC is smaller than a combined width W2 of the second portion P2 of the channel pillar CP and the charge storage structure 108 surrounding the second portion P2. The width W0 of the string selection line cut slit SSLC is greater than the thickness T3 of the charge storage structure 108, but is smaller than twice the thickness T3 of the charge storage structure 108. The string selection line cut slit SSLC includes the tunneling layer 122, the charge storage layer 123, and the blocking layer 124 of the charge storage structure 108. The string selection line cut slit SSLC does not include the channel layer 110.

Referring to FIG. 2B, the conductive plug COA extends through the dielectric layer 228 and is electrically connected to the conductive cap 114 of the channel pillar CP. The conductive plug COA has an inverted-U shape. A main body part MP of the conductive plug COA is in contact with the top surface and the upper sidewall of the conductive cap 114. The bottom surface and the lower sidewall of an extension part EP of the conductive plug COA are in contact with the charge storage structure 108.

Referring to FIG. 4, in at least one embodiment, a device layer 60, an interconnect structure 70, and a source line layer SL may be provided below the stacked structure (with a memory array) GSK as described in the previous paragraphs and above the substrate 100. The device layer 60 may include complementary metal-oxide-semiconductor devices. In some embodiments, these complementary metal-oxide-semiconductor devices and the interconnect structure 70 may be formed before formation of the stacked structure GSK, and may thus be located below the memory array. This type is also referred to as a memory having a complementary metal-oxide-semiconductor under array (CMOS under array, CuA) structure.

Referring to FIG. 5, in some other embodiments, before forming the stacked structure GSK, a source line layer SL is first formed over the substrate 100 (shown in FIG. 1J). Afterwards, after forming the stacked structure GSK, the stacked structure SK2, the conductive plugs COA, COA1, and COA2, and the bit lines BL over the substrate 100 according to the methods of the above embodiment, a bonding layer 80A is first formed. Then, a substrate 50 with the device layer 60 and the interconnect structure 70 as described in the previous paragraphs and a bonding layer 80B is provided. Next, the substrate 100 is flipped. The bonding layer 80A and the bonding layer 80B are bonded to each other to form a bonding structure 80. The substrate 100 may be polished and completely removed or thinned (not shown). Then, an interconnect structure 138 and a protective layer 140 are formed over the stacked structure GSK. The substrate 50, the device layer 60, the interconnect structure 70 and bonding structure 80 are under the stacked structure GSK. The second portion P2 of the channel pillar CP is near to the substrate 50. The first portion P1 of the channel pillar CP is away from the substrate 50. In this manner, the complementary metal-oxide-semiconductor devices are formed below the memory array by bonding. This type is also referred to as a complementary metal-oxide-semiconductor bonding array (CMOS bonding array, CbA) structure.

Based on the above, in the memory device and the method of fabricating the same according to the embodiments of the disclosure, it is possible to reduce the size of the string selection line cut slit and reduce the distance between the string selection line cut slit and the channel pillars to reduce the chip area occupied. Furthermore, the disclosure can simplify the fabrication process, integrate with existing processes, increase integration, improve the process yield, and reduce the fabrication costs.

What is claimed is:

1. A memory device comprising:
a stacked structure comprising a plurality of first insulating layers and a plurality of first conductive layers stacked alternately;
a second conductive layer over the stacked structure;
a plurality of channel pillars extending through the second conductive layer and the stacked structure, wherein each of the plurality of channel pillars comprises:
a first portion extending through the stacked structure; and
a second portion on the first portion and extending through the second conductive layer, wherein a diameter of the first portion is greater than a diameter of the second portion;
a plurality of charge storage structures, surrounding the plurality of channel pillars and in contact with the second conductive layer; and
a string selection line cut slit extending through the second conductive layer and disposed between the second portions of two adjacent channel pillars among the plurality of channel pillars.

2. The memory device according to claim 1, further comprising a substrate underlying the stacked structure.

3. The memory device according to claim 1, wherein a second distance between the second portions of two adjacent channel pillars is greater than a first distance between the first portions of the two adjacent channel pillars.

4. The memory device according to claim 3, wherein a third distance between the string selection line cut slit and a second portion of a neighboring channel pillar is smaller than the second distance.

5. The memory device according to claim 1, wherein a region between the string selection line cut slit and a second portion of a neighboring channel pillar is free of a dummy pillar.

6. The memory device according to claim 3, further comprising a separation wall extending through the second conductive layer and the stacked structure, wherein a fourth distance between the separation wall and a second portion of another channel pillar is greater than the third distance.

7. The memory device according to claim 1, wherein a sidewall of the string selection line cut slit is in contact with the second conductive layer.

8. The memory device according to claim 1, wherein the string selection line cut slit does not extend beyond a topmost first conductive layer of the stacked structure.

9. The memory device according to claim 1, wherein a thickness of the second conductive layer is greater than a thickness of each of the plurality of first conductive layers.

10. The memory device according to claim 1, wherein the second portion comprises:
a conductive cap;
a second insulating layer located below the conductive cap; and
a channel layer located between the charge storage structure and the second insulating layer, wherein the charge storage structure surrounds the channel layer, the second insulating layer, and the conductive cap and is in contact with the second conductive layer.

11. The memory device according to claim 10, wherein a width of the string selection line cut slit is smaller than twice a thickness of the charge storage structure.

12. The memory device according to claim 10, wherein the string selection line cut slit comprises the charge storage structure but is free of a channel layer.

13. The memory device according to claim 10, wherein the first portion comprises an air gap surrounded by the second insulating layer, and the second portion is free of an air gap.

14. The memory device according to claim 1, wherein the string selection line cut slit has a wavy shape in a top view.

15. A memory device comprising:
a stacked structure comprising a plurality of insulating layers and a plurality of first conductive layers stacked alternately;
a second conductive layer between the stacked structure and an interconnect layer having a plurality of conductive plugs;
a string selection line cut slit extending through the second conductive layer;
a plurality of first channel pillars extending through the second conductive layer and the stacked structure in a first sub-zone; and
a plurality of second channel pillars extending through the second conductive layer and the stacked structure in a second sub-zone,
wherein the string selection line cut slit is arranged between the plurality of first channel pillars and the plurality of second channel pillars, and the string selection line cut slit has a wavy shape in a top view and divides the second conductive layer into a first sub-zone and a second sub-zone.

16. The memory device according to claim 15, wherein the string selection line cut slit does not extend beyond a topmost first conductive layer of the stacked structure.

17. The memory device according to claim 15, further comprising a separation wall extending through the second conductive layer and the stacked structure, wherein the separation wall has a strip shape different from the wavy shape of the string selection line cut slit.

18. The memory device according to claim 15, wherein an interface region between the first sub-zone region and the second sub-zone region is free of a dummy pillar.

19. The memory device according to claim 15, wherein the string selection line cut slit is conformal with partial sidewalls of the plurality of first channel pillars and partial sidewalls of the plurality of second channel pillars.

20. A method of fabricating a memory device, comprising:
forming a plurality of first openings in a stacked structure, wherein the stacked structure comprises a plurality of first insulating layers and a plurality of intermediate layers stacked alternately;
filling the plurality of first openings with a sacrificial material;
forming a conductive layer over the stacked structure;
patterning the conductive layer to form a plurality of second openings and a trench between the plurality of second openings, wherein a width of the trench is smaller than widths of the plurality of second openings;
removing the sacrificial material to expose the plurality of first openings below the plurality of second openings;
forming a plurality of channel pillars in the plurality of first openings and the plurality of second openings; and
forming a string selection line cut slit in the trench.
